(19) United States
(12) Patent Application Publication
(10) Pub. No.: US 2012/0099282 A1
(43) Pub. Date: Apr. 26, 2012

(54) Electronic Device and Flexible Printed Wiring Board

(76) Inventor: Kenji Hasegawa, Tokyo (JP)

(21) Appl. No.: 13/096,807

(22) Filed: Apr. 28, 2011

(30) Foreign Application Priority Data
Oct. 20, 2010 (JP) 2010-235774

(51) Int. Cl. H05K 1/02; H05K 5/00

(52) U.S. Cl. 361/749

(57) ABSTRACT

According to one embodiment, an electronic device includes a housing and a flexible printed wiring board at least part of which is housed in the housing. The flexible printed wiring board includes a base layer, a first layer, and a second layer. The base layer includes a first surface provided with a conductor pattern. The first layer covers the first surface and the conductor pattern such that the first surface and the conductor pattern are exposed at an edge portion of the base layer. The second layer covers a second surface of the edge portion of the base layer. A first edge of the first layer and a second edge of the second layer are provided with a convex-concave shape that is convex or concave along the first surface or the second surface of the base layer. The first edge is located on the edge portion side, and the second edge is located on the back of the first edge.

### CROSS-REFERENCE TO RELATED APPLICATIONS

This application is based upon and claims the benefit of priority from Japanese Patent Application No. 2010-235774, filed Oct. 20, 2010, the entire contents of which are incorporated herein by reference.

### FIELD

Embodiments described herein relate generally to an electronic device and a flexible printed wiring board.

### BACKGROUND

There have been known electronic devices provided with a flexible printed wiring board in the housing.

With regard to this type of electronic devices, it is required that there is little chance of such events as wiring disconnection in the conductor pattern of the flexible printed wiring board.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary perspective view of an electronic device according to an embodiment;

FIG. 2 is an exemplary schematic plan view of a circuit board and a flexible printed wiring board in the housing of the electronic device in the embodiment;

FIG. 3 is an exemplary plan view of an edge of the flexible printed wiring board viewed from the front surface in the embodiment;

FIG. 4 is an exemplary plan view of the edge of the flexible printed wiring board viewed from the back surface in the embodiment;

FIG. 5A is an exemplary plan view of a first layer of the edge of the flexible printed wiring board viewed from the front surface in the embodiment;

FIG. 5B is an exemplary plan view of a base layer of the edge of the flexible printed wiring board viewed from the front surface in the embodiment;

FIG. 50 is an exemplary plan view of a second layer of the edge of the flexible printed wiring board viewed from the front surface in the embodiment;

FIG. 6 is an exemplary plan view of the edge of the flexible printed wiring board where a first convex portion, a conductor pattern, and a second convex portion overlap one on top of another in the embodiment;

FIG. 7 is an exemplary cross-sectional view taken along line VII-VII of FIG. 6 in the embodiment;

FIG. 8 is an exemplary plan view of the edge of the flexible printed wiring board where the first convex portion, the conductor pattern, and the second convex portion overlap one on top of another, and the first and second layers are each displaced from a predetermined position in the embodiment; and

FIG. 9 is an exemplary plan view of the edge of the flexible printed wiring board where a first convex portion, a conductor pattern, and a second convex portion overlap one on top of another according to a modification of the embodiment.

### DETAILED DESCRIPTION

In general, according to one embodiment, an electronic device comprises a housing and a flexible printed wiring board at least part of which is housed in the housing. The flexible printed wiring board comprises a base layer, a first layer, and a second layer. The base layer includes a first surface provided with a conductor pattern. The first layer covers the first surface and the conductor pattern such that the first surface and the conductor pattern are exposed at an edge portion of the base layer. The second layer covers a second surface of the edge portion of the base layer. A first edge of the first layer and a second edge of the second layer are provided with a convex-concave shape that is convex or concave along the first surface or the second surface of the base layer. The first edge is located on the edge portion side, and the second edge is located on the back of the first edge.

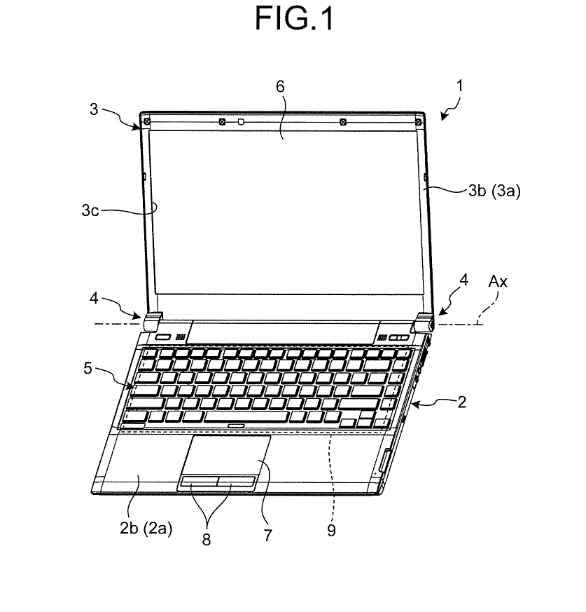

Exemplary embodiments will be described in detail below with reference to the accompanying drawings. As illustrated in FIG. 1, an electronic device 1 of an embodiment is, for example, a notebook personal computer. The electronic device 1 comprises a flat rectangular first body 2 and a flat rectangular second body 3. The first body 2 and the second body 3 are connected by a hinge 4 to be relatively rotatable about a rotation axis Ax between an open position (FIG. 1) and a closed position (not illustrated).

The first body 2 is provided with a keyboard 5, a pointing device 7, click buttons 8, and the like as input devices, which are exposed on a front surface 2b as the outer surface of a housing 2a of the first body 2. The second body 3 is provided with a display 6, i.e., a display device, such as a liquid crystal display (LCD) as an electronic component, which is exposed from an opening 3c on a front surface 3b as the outer surface of a housing 3a. In the open position as illustrated in FIG. 1, the keyboard 5, the display 6, the pointing device 7, the click buttons 8, and the like are exposed so that the user can use them. On the other hand, in the closed position (not illustrated), the front surface 2b closely faces the front surface 3b, and the keyboard 5, the display 6, the pointing device 7, the click buttons 8, and the like are hidden between the housings 2a and 3a.

The housing 2a of the first body 2 houses a circuit board assembly including a circuit board 9 having a central processing unit (CPU), a read only memory (ROM), a random access memory (RAM), and other electronic components mounted thereon. The housing 2a also houses components (not illustrated) such as a hard disk, a cooling fan, and the like.

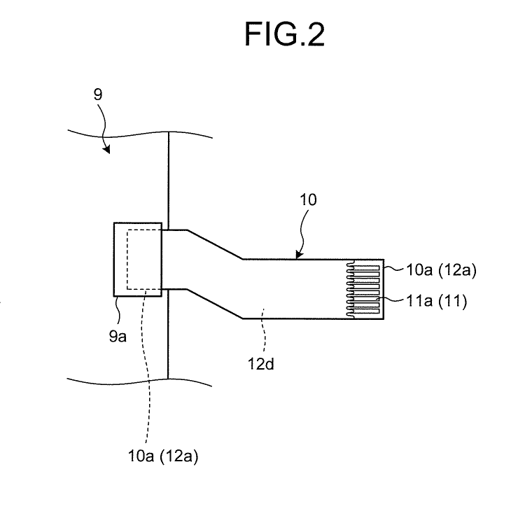

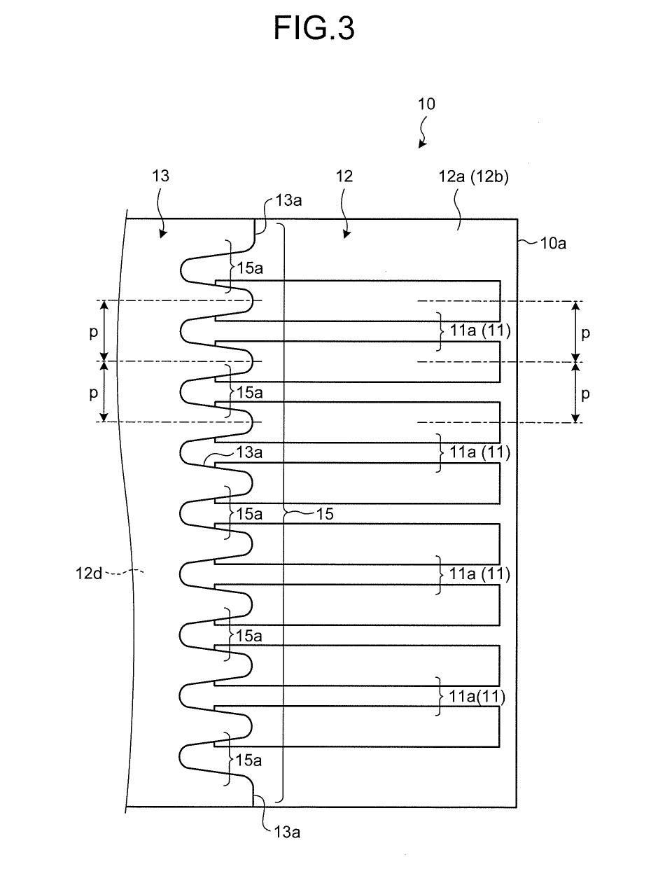

As illustrated in FIG. 2, the circuit board 9 is provided with a connector 9a. An edge 10a (the left edge in FIG. 2) of a flexible printed wiring board 10 is inserted to the connector 9a, and thereby the flexible printed wiring board 10 is attached to the circuit board 9. The other edge 10a (the right edge in FIG. 2) of the flexible printed wiring board 10 is inserted to a connector (not illustrated) of another circuit board (not illustrated) or the like. That is, the flexible printed wiring board 10 functions as a component that electrically connects two components (circuit boards, etc.). The edge 10a of the flexible printed wiring board 10 (an edge 12a of a base layer 12) refers to the edge in the direction in which conductor patterns 11 (see FIG. 3, etc.) are routed. At the edge 10a (12a), generally, terminal portions 11a (see FIG. 3, etc.) of the conductor patterns 11 are exposed.

The flexible printed wiring board 10 of the embodiment is formed into a relatively thin film-like, sheet-like, or plate-like shape. The flexible printed wiring board 10 is flexible and elastic. Accordingly, the flexible printed wiring board 10 is arranged as being bent inside or between the housings 2a and 3a, and the like, or is used as being bendable and stretchable between two components capable of relative movement (for example, the first body 2 and the second body 3).

As illustrated in FIGS. 3 to 7, the flexible printed wiring board 10 of the embodiment comprises the base layer (base portion) 12, a first layer (first portion) 13, and a second layer (second portion) 14. The first layer 13 covers a front surface 12b of the base layer 12. The second layer 14 covers a back surface 12c of the edge 12a of the base layer 12.

All the base layer 12, the first layer 13, and the second layer 14 are made of a relatively thin film-like, sheet-like, or plate-like material having flexibility and elasticity. Besides, all the base layer 12, the first layer 13, and the second layer 14 are made of an insulating material. The base layer 12, the first layer 13, and the second layer 14 are bonded to one another, thereby forming the flexible printed wiring board 10. More specifically, the base layer 12, the first layer 13, and the second layer 14 may be made of, for example, polyimide or the like. Each of the base layer 12, the first layer 13, and the second layer 14 may be formed by bonding two or more materials together or the like.

As illustrated in FIG. 3, the plurality of conductor patterns 11 are provided to at least the front surface 12b of the base layer 12. The conductor patterns 11 may be made of, for example, a conductive metal material such as copper foil. For example, the conductor patterns 11 may be formed by bonding copper foil to the front surface 12b of the base layer 12 and etching a predetermined pattern using a mask. The conductor patterns 11 are arranged spaced apart in parallel relation to each other, and are mutually insulated.

As illustrated in FIGS. 3, 6, and the like, each of the conductor patterns 11 comprises a wiring portion 11b and the terminal portion 11a connected to the wiring portion 11b. The wiring portion 11b is relatively narrow in width, while the terminal portion 11a is relatively wide. The terminal portion 11a is provided at least one end (both ends in the embodiment) of the conductor pattern 11. Incidentally, a plurality of the terminal portions 11a may be provided as being branched from the one wiring portion 11b.

As illustrated in FIG. 2, the first layer 13 covers almost entirely over a center portion 12d of the base layer 12 except the edge 12a. In this sense, the first layer 13 corresponds to a cover (cover layer). As described above, the plurality of conductor patterns 11 are provided to the front surface 12b of the base layer 12. Accordingly, the first layer 13 corresponds to an insulating cover for the conductor patterns 11. The edge 12a of the base layer 12 is not covered with the first layer 13, and, together with the frond surface 12b, corresponds to a terminal exposure portion where the terminal portions 11a of the conductor patterns 11 are exposed.

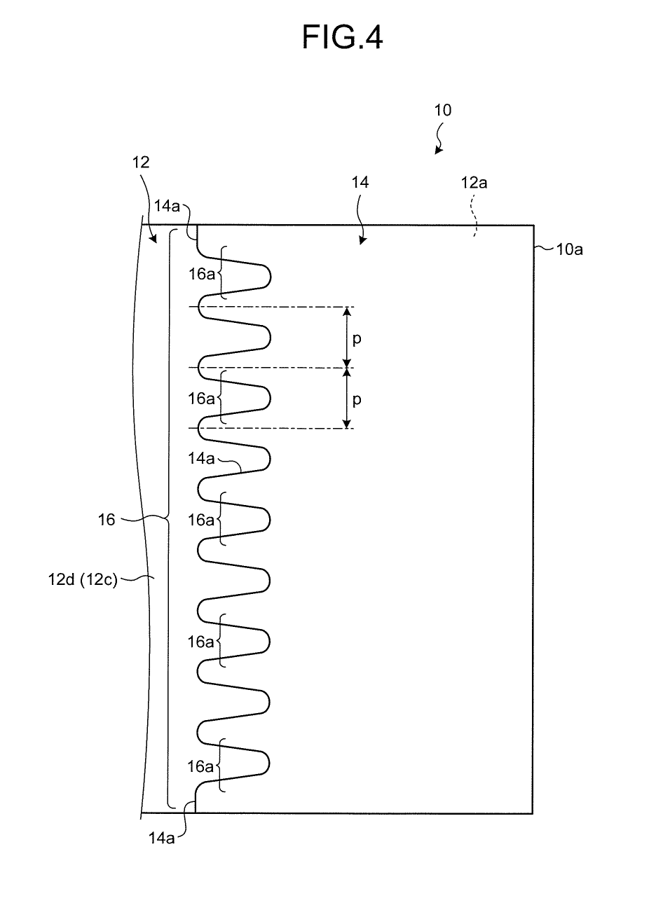

On the other hand, as illustrated in FIG. 4, the second layer 14 covers the back surface 12c of the edge 12a of the base layer 12. As described above, the edge 12a of the front surface 12b of the base layer 12 is not covered with the first layer 13. Therefore, unless countermeasures are taken, the rigidity and strength of the edge 10a of the flexible printed wiring board 10 relatively decrease. In view of this, according to the embodiment, the second layer 14 is provided to improve the rigidity and strength of the edge 10a of the flexible printed wiring board 10. Thus, the second layer 14 corresponds to a reinforcing member (reinforcement layer).

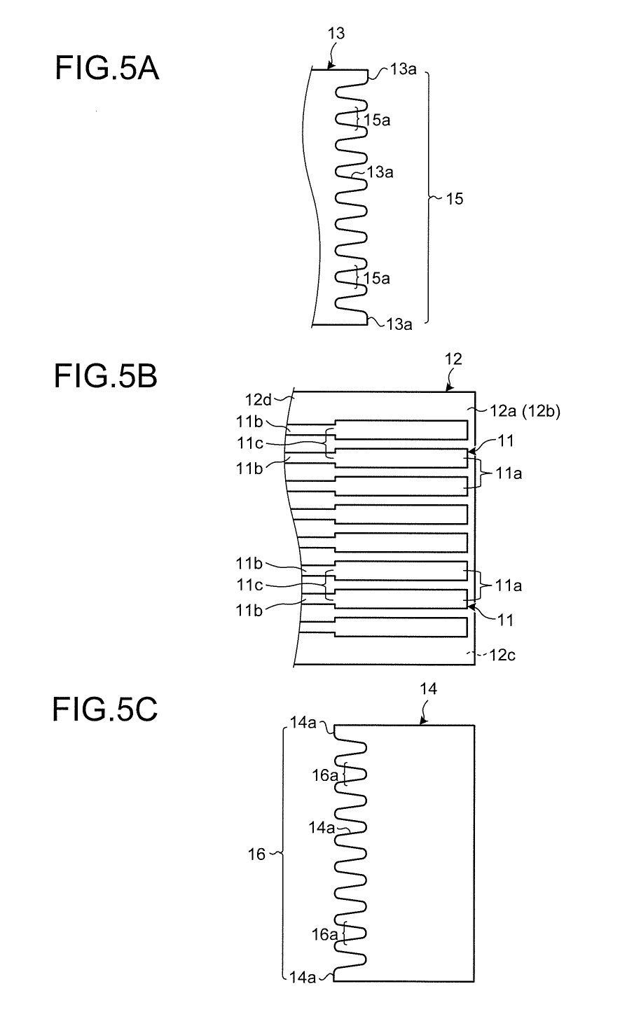

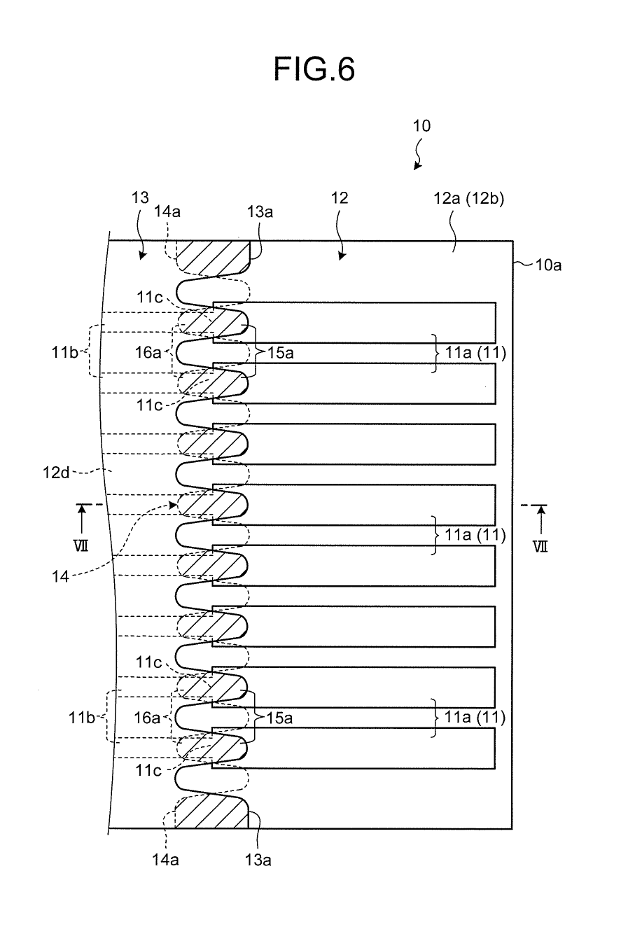

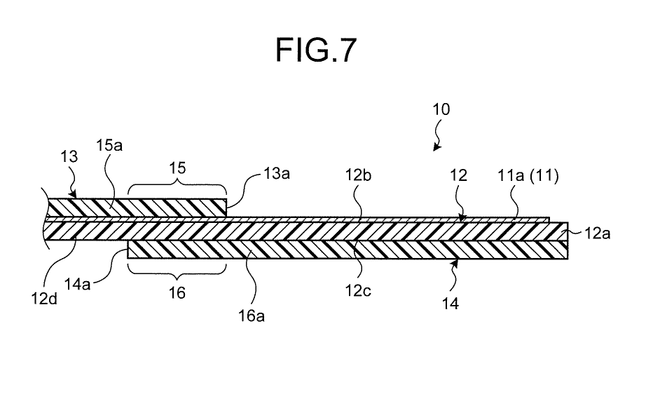

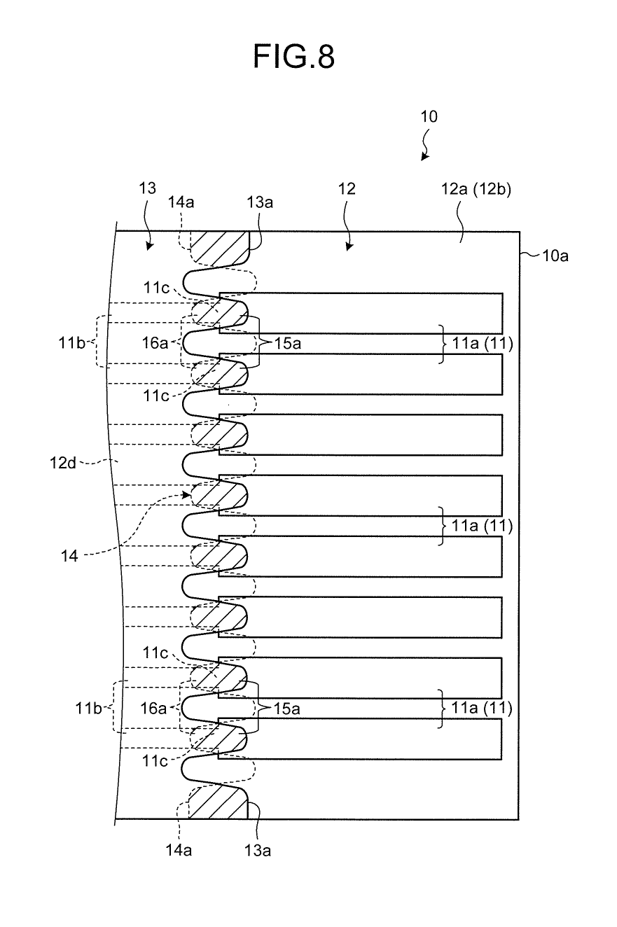

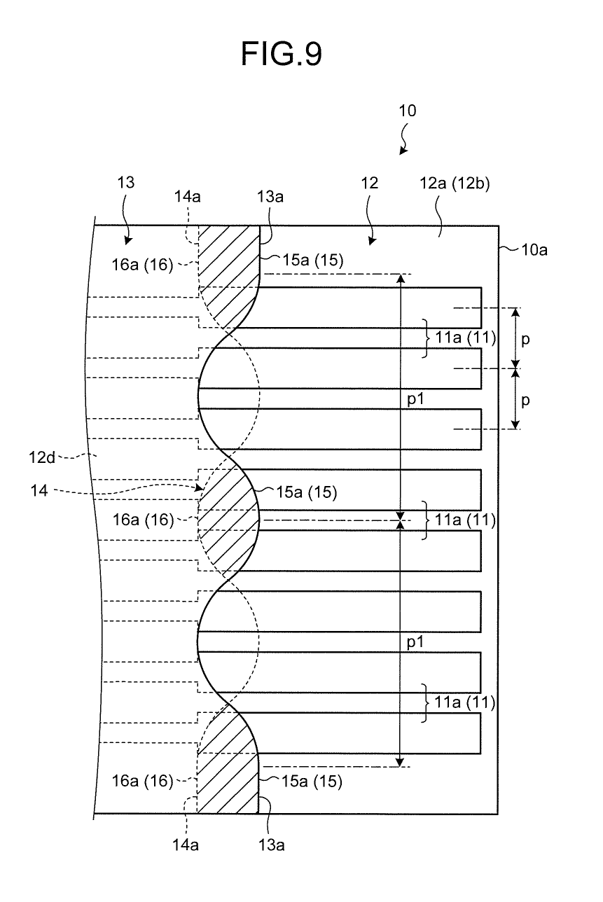

As the second layer 14 extends longer toward the center portion 12d, problems are more likely to occur, for example, the bendability of the flexible printed wiring board 10 decreases, and the flexible printed wiring board 10 is more likely to interfere with another component. Accordingly, the second layer 14 is generally provided as covering the back surface 12c of the edge 12a of the base layer 12. As a result, as illustrated in FIGS. 5 and 6, the first layer 13 that covers the front surface 12b of the center portion 12d of the base layer 12 except the edge 12a and the second layer 14 that covers the back surface 12c of the edge 12a are arranged in such a positional relation that an edge 13a (first edge) of the first layer 13 on the edge 12a side and an edge 14a (second edge) of the second layer 14 almost overlap at the front and back. Assuming that if the edges 13a and 14a are shaped in a straight line, along with the bending of the flexible printed wiring board 10, the stress is concentrated on a narrow area of the base layer 12 adjacent to the edges 13a and 14a. This induces such events as wiring disconnection in the conductor patterns 11 and the bending of the base layer 12.

For this reason, according to the embodiment, the edges 13a and 14a are provided with convex-concave shapes 15 and 16 that are convex or concave along the front surface 12b or the back surface 12c of the base layer 12. The edge 14a having the convex-concave shape 16 is located at the back of the edge 13a having the convex-concave shape 15. That is, according to the embodiment, as the edges 13a and 14a have the convex-concave shapes 15 and 16, an area of the base layer 12 where a force is applied from the first layer 13 or the second layer 14 when the flexible printed wiring board 10 is bent is relatively wider in the longitudinal direction of the base layer 12 (the direction in which the conductor patterns 11 are routed, the horizontal direction in FIGS. 3 to 7). This reduces the concentration of stress, and suppresses such events as wiring disconnection in the conductor patterns 11 and the bending of the base layer 12.

According to the embodiment, the convex-concave shape 15 includes a first convex portion 15a (a portion protruding outward viewed from the gravity center side of the first layer 13) at the edge 13a of the first layer 13. Meanwhile, the convex-concave shape 16 includes a second convex portion 16a (a portion protruding outward viewed from the gravity center side of the second layer 14) at the edge 14a of the second layer 14. As illustrated in FIGS. 6 and 7, at least part of the first convex portion 15a overlaps at least part of the second convex portion 16a in the front-back direction of the base layer 12. With this, at overlapping portions where the first convex portion 15a and the second convex portion 16a overlap (hatched portion in FIG. 6), the rigidity and strength of the flexible printed wiring board 10 are improved. Thus, if the flexible printed wiring board 10 is bent, the base layer 12 is less likely to be bent.

According to the embodiment, there are a plurality of overlapping portions where the first convex portion 15a and the second convex portion 16a overlap in the front-back direction of the base layer 12 (hatched portion in FIG. 6). Thus, compared to the case of one overlapping portion, the rigidity and strength of the flexible printed wiring board 10 can be further improved. The overlapping portions are distributed in the width direction of the flexible printed wiring board 10 (the direction perpendicular to the direction in which the conductor patterns 11 are routed, the vertical direction in FIGS. 3 to 6). With this, the rigidity and strength of the flexible printed wiring board 10 can be further improved.

According to the embodiment, the overlapping portions where the first convex portion 15a and the second convex portion 16a overlap in the front-back direction of the base layer 12 are provided at least one edge (both edges in the embodiment) in the width direction of the flexible printed wiring board 10. Thus, when the flexible printed wiring board 10 is twisted, the width direction edge of the flexible printed wiring board 10 is less likely to be damaged.

According to the embodiment, as illustrated in FIG. 3, a plurality of the first convex portions 15a are arranged at a predetermined pitch p. Further, as illustrated in FIG. 4, a plurality of the second convex portions 16a are arranged at the pitch p in the same manner as the first convex portions 15a. Thus, it is possible to relatively easily obtain the structure in which the first convex portions 15a and the second convex portions 16a overlap in the front-back direction of the base layer 12 at a plurality of positions, and the overlapping portions are distributed in the width direction of the flexible printed wiring board 10.

According to the embodiment, as illustrated in FIG. 6, the conductor pattern 11 is interposed between the first convex portion 15a and the second convex portion 16a in the front-back direction of the base layer 12. Thus, the level of protection afforded to the conductor patterns 11 can be increased.

According to the embodiment, as illustrated in FIG. 3, the plurality of conductor patterns 11 are arranged at the pitch p in the same manner as the first convex portions 15a and the second convex portions 16a. As illustrated in FIG. 6, the conductor patterns 11 are interposed between the first convex portions 15a and the second convex portions 16a, respectively, in the front-back direction. This structure increases the level of protection afforded to the conductor patterns 11. Besides, it is possible to relatively easily obtain the structure in which the conductor patterns 11 are interposed between the first convex portions 15a and the second convex portions 16a, respectively, in the front-back direction of the base layer 12 at a plurality of positions, and the overlapping portions are distributed where the first convex portions 15a and the second convex portions 16a overlap in the front-back direction of the base layer 12 and thereby the rigidity and strength are improved.

According to the embodiment, as illustrated in FIG. 6, a boundary 11c between the terminal portion 11a and the wiring portion 11b of the conductor pattern 11 is interposed between the first convex portion 15a and the second convex portion 16a in the front-back direction of the base layer 12. The boundary 11c is a portion which is suddenly deformed and where stress is likely to be concentrated. In regard to this point, as the base layer 12 and the boundary 11c are interposed between the first convex portion 15a and the second convex portion 16a in the front-back direction of the base layer 12, the rigidity and strength are improved at the portion. Thus, when the flexible printed wiring board 10 is twisted, the boundary 11c of the conductor pattern 11 is less likely to be damaged.

According to the embodiment, as illustrated in FIG. 6, at least one (both in the embodiment) of the convex-concave shape 15 of the first edge 13a and the convex-concave shape 16 of the second edge 14a is curbed. Thus, it is possible to reduce the damage to the edge 13a or 14a due to the concentration of stress on a portion that is suddenly deformed in the convex-concave shape 15 or 16.

Further, according to the embodiment, at least one (both in the embodiment) of the convex-concave shape 15 of the edge 13a and the convex-concave shape 16 of the edge 14a is curved in a wavy manner. This enables not only to reduce the damage to the edge 13a or 14a due to the concentration of stress on a portion that is suddenly deformed in the convex-concave shape 15 or 16, but also to relatively easily obtain the structure in which the first convex portions 15a and the second convex portions 16a are arranged at the predetermined pitch p.

As described above, according to the embodiment, the first convex portions 15a and the second convex portions 16a are arranged so that they overlap in the front-back direction of the base layer 12. Thus, as illustrated in FIG. 8, even if the first layer 13 or the second layer 14 is displaced with respect to the base layer 12 or the conductor pattern 11, there can be obtained a portion where the first layer 13 and the second layer 14 overlap in the front-back direction of the base layer 12. That is, the structure, in which the first convex portions 15a and the second convex portions 16a overlap in the front-back direction of the base layer 12, as described in the embodiment offers high robustness to reduce stress concentration.

The above embodiment is susceptible to several modifications and variations. For example, as illustrated in FIG. 9, the first convex portions 15a and the second convex portions 16a may be arranged at a pitch p1 different from the pitch p at which the conductor patterns 11 are arranged. In this case also, it is possible to achieve the effect of the convex-concave shapes 15 and 16 provided to the edges 13a and 14a as well as the effect of the first convex portions 15a and the second convex portions 16a overlapping in the front-back direction of the base layer 12.

While the above embodiment is described as being applied to a notebook personal computer, it may also be applicable to other electronic devices provided with a flexible printed wiring board, such as desktop personal computers, televisions, and mobile phones.

Besides, regarding the electronic device, the housing, the flexible printed wiring board, the conductor pattern, the base layer, the first layer, the second layer, the first edge, the second edge, the convex-concave shape, the first convex portion, the second convex portion, the pitch, and the like, the specifications (structure, shape, material, size, length, width, thickness, number, arrangement, position, etc.) can be suitably modified.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic device comprising:
a housing;
a flexible printed wiring board at least part of which is housed in the housing, the flexible printed wiring board comprising
a base layer including a first surface provided with a conductor pattern;
a first layer that covers the first surface and the conductor pattern such that the first surface and the conductor pattern are exposed at an edge portion of the base layer; and
a second layer that covers a second surface of the edge portion of the base layer, wherein
a first edge of the first layer and a second edge of the second layer are provided with a convex-concave shape that is convex or concave along the first surface or the second surface of the base layer, the first edge being located on a side of the edge portion, the second edge being located on a back of the first edge.

2. The electronic device of claim 1, wherein
the convex-concave shape of the first edge comprises a first convex portion,
the convex-concave shape of the second edge comprises a second convex portion, and
at least part of the first convex portion and at least part of the second convex portion overlap in a front-back direction of the base layer.

3. The electronic device of claim 2 further comprising a plurality of combinations of the first convex portion and the second convex portion that overlap in the front-back direction.

4. The electronic device of claim 3, wherein
the convex-concave shape of the first edge comprises a plurality of first convex portions that are arranged at a predetermined pitch, and
the convex-concave shape of the second edge comprises a plurality of second convex portions that are arranged at the predetermined pitch.

5. The electronic device of claim 2, wherein the conductor pattern is interposed between the first convex portion and the second convex portion in the front-back direction of the base layer.

6. The electronic device of claim 4, wherein
the conductor pattern includes a plurality of conductor patterns that are arranged at the predetermined pitch, and
the conductor patterns are interposed between the first convex portions and the second convex portions, respectively, in the front-back direction of the base layer.

7. The electronic device of claim 5, wherein
the conductor pattern comprises a terminal portion and a wiring portion connected to the terminal portion, the terminal portion being exposed at the edge portion, the wiring portion being less in width than the terminal portion and covered with the first layer, and
a boundary between the terminal portion and the wiring portion is interposed between the first convex portion and the second convex portion in the front-back direction of the base layer.

8. The electronic device of claim 1, wherein at least one of the first edge and the second edge is provided with the convex-concave shape that is curved.

9. The electronic device of claim 8, wherein at least one of the first edge and the second edge is provided with the convex-concave shape that is curved in a wavy manner.

10. An electronic device comprising:
a housing;
a flexible printed wiring board at least part of which is housed in the housing, the flexible printed wiring board comprising
a base portion including a first surface provided with a conductor pattern;
a first portion that covers the first surface and the conductor pattern such that the first surface and the conductor pattern are exposed at an edge portion of the base portion; and
a second portion that covers a second surface of the edge portion of the base portion, wherein
a first edge of the first portion and a second edge of the second portion are provided with a convex portion that is convex along the first surface or the second surface of the base portion, the first edge being located on a side of the edge portion, the second edge being located on a back of the first edge.

11. A flexible printed wiring board comprising:
a base layer including a first surface provided with a conductor pattern;
a first layer that covers the first surface and the conductor pattern such that the first surface and the conductor pattern are exposed at an edge portion of the base layer; and
a second layer that covers a second surface of the edge portion of the base layer, wherein
a first edge of the first layer and a second edge of the second layer are provided with a convex-concave shape that is convex or concave along the first surface or the second surface of the base layer, the first edge being located on a side of the edge portion, the second edge being located on a back of the first edge.
